(19) United States
(12) Patent Application Publication
(10) Pub. No.: US 2025/0203853 A1
(43) Pub. Date: Jun. 19, 2025

(54) SEMICONDUCTOR DEVICE

(71) Applicant: Samsung Electronics Co., Ltd., Suwon-si (KR)

(72) Inventors: Jinwoo HAN, Suwon-si (KR); Seokhan PARK, Suwon-si (KR); Bowon YOO, Suwon-si (KR); Gyuhwan OH, Suwon-si (KR)

(73) Assignee: Samsung Electronics Co., Ltd., Suwon-si (KR)

(21) Appl. No.: 18/945,728

(22) Filed: Nov. 13, 2024

(30) Foreign Application Priority Data
Dec. 14, 2023 (KR) 10-2023-0182241

(51) Int. Cl. H10B 12/00

(52) U.S. Cl. CPC H10B 12/488; H10B 12/482; H10B 12/50

(57) ABSTRACT

A semiconductor device includes a substrate, word lines stacked on the substrate, bit lines at one side of the word lines and extending in a vertical direction, capacitor structures at another side of the word lines facing the one side of the word lines and extending in a first horizontal direction, first horizontal extensions extending in the first horizontal direction and stacked on the substrate, and second horizontal extensions connected to the first horizontal extensions, respectively, wherein a group of word lines at a certain vertical level from among the word lines are connected to one first horizontal extension at a same vertical level as the group of word lines from among the first horizontal extensions, and a word line contact is on one second horizontal extension from among the second horizontal extensions.

### CROSS-REFERENCE TO RELATED APPLICATION

This application is based on and claims priority under 35 U.S.C. § 119 to Korean Patent Application No. 10-2023-0182241, filed on Dec. 14, 2023, in the Korean Intellectual Property Office, the disclosure of which is incorporated by reference herein in its entirety.

### BACKGROUND

The inventive concepts relate to semiconductor devices, and more particularly, to semiconductor devices including a three-dimensional (3D) semiconductor memory element.

As electronic products become more compact, multi-functional, and high-performance, high-capacity semiconductor memory elements are required, and to provide high-capacity semiconductor memory elements, increased integration is required. A degree of integration of two-dimensional semiconductor memory elements according to the related art is mainly determined by an area occupied by a unit memory cell, and thus the degree of integration of two-dimensional semiconductor memory elements is increasing but is still limited. Accordingly, a semiconductor device including a 3D semiconductor memory element that increases memory capacity by stacking a plurality of memory cells in a vertical direction on a substrate has been proposed.

### SUMMARY

The inventive concepts provide semiconductor devices with improved integration of semiconductor memory elements.

According to an aspect of the inventive concepts, a semiconductor device may include a substrate, a plurality of word lines stacked on the substrate, a plurality of bit lines at one side of the plurality of word lines, the plurality of bit lines extending in a vertical direction perpendicular to an upper surface of the substrate, a plurality of capacitor structures at another side of the plurality of word lines, the another side of the plurality of word lines facing the one side of the plurality of word lines, the plurality of capacitor structures extending in a first horizontal direction parallel to the upper surface of the substrate, a plurality of first horizontal extensions extending in the first horizontal direction and stacked on the substrate, and a plurality of second horizontal extensions connected to the plurality of first horizontal extensions, respectively, wherein a group of word lines at a certain vertical level from among the plurality of word lines are connected to one first horizontal extension at a same vertical level as the group of word lines from among the plurality of first horizontal extensions, and a word line contact is on one second horizontal extension connected to the first horizontal extension from among the plurality of second horizontal extensions.

According to another aspect of the inventive concepts, a semiconductor device may include a substrate, a peripheral circuit structure on the substrate, the peripheral circuit structure including a plurality of bit line sense amplifiers, a plurality of first word lines stacked on the substrate, a plurality of second word lines stacked on the substrate, the plurality of second word lines being apart from the plurality of first word lines in a first horizontal direction parallel to an upper surface of the substrate, a plurality of first bit lines at one side of the plurality of first word lines, the plurality of first bit lines extending in a vertical direction perpendicular to the upper surface of the substrate, a plurality of first capacitor structures at another side of the plurality of first word lines, the another side of the plurality of first word lines facing the one side of the plurality of first word lines, the plurality of first capacitor structures extending in the first horizontal direction, a plurality of second bit lines at one side of the plurality of second word lines adjacent to the one side of the plurality of first word lines, the plurality of second bit lines extending in the vertical direction, a plurality of second capacitor structures at another side of the plurality of second word lines, the another side of the plurality of second word lines facing the one side of the plurality of second word lines, the plurality of second capacitor structures extending in the first horizontal direction, a plurality of first horizontal extensions extending in the first horizontal direction and stacked on the substrate, and a plurality of second horizontal extensions connected to the plurality of first horizontal extensions, respectively, wherein a group of first word lines at a certain vertical level from among the plurality of first word lines are connected to one first horizontal extension at a same vertical level as the group of first word lines from among the plurality of first horizontal extensions, at least one first word line contact is on one second horizontal extension connected to the first horizontal extension from among the plurality of second horizontal extensions, a group of second word lines at a certain vertical level from among the plurality of second word lines are connected to another first horizontal extension at a same vertical level as the second word lines from among the plurality of first horizontal extensions, and at least one second word line contact is on another second horizontal extension connected to the another first horizontal extension from among the plurality of first horizontal extensions.

According to another aspect of the inventive concepts, a semiconductor device may include a substrate, a peripheral circuit structure on the substrate, the peripheral circuit structure including a plurality of bit line sense amplifier, and a cell array structure on the peripheral circuit structure, the cell array structure including a first memory cell block and a second memory cell block, wherein each of the first memory cell block and the second memory cell block includes a plurality of first word lines stacked on the substrate, a plurality of second word lines stacked on the substrate and apart from the plurality of first word lines in a first horizontal direction parallel to an upper surface of the substrate, a plurality of first bit lines at one side of the plurality of first word lines, the plurality of first bit lines extending in a vertical direction perpendicular to the upper surface of the substrate, a plurality of second bit lines at one side of the plurality of second word lines adjacent to the one side of the plurality of first word lines, the plurality of second bit lines extending in the vertical direction, a plurality of first horizontal extensions extending in the first horizontal direction and stacked on the substrate, and a plurality of second horizontal extensions connected to the plurality of first horizontal extensions, respectively, a group of first word lines at a certain vertical level from among the plurality of first word lines are connected to one first horizontal extension at a same vertical level as the group of first word lines from among the plurality of first horizontal extensions, at least one first word line contact is on a second horizontal extension connected to the one first horizontal extension, a group of second word lines at a certain vertical level from among the plurality of second word lines are connected to another first horizontal extension at a same vertical level as the group of second word lines from among the plurality of first horizontal extensions, and at least one second word line contact is on another second horizontal extension connected to the another first horizontal extension, and a first word line adjacent to the second memory cell block from among the plurality of first word lines of the first memory cell block and a first word line adjacent to the first memory cell block from among the plurality of second word lines of the second memory cell block are connected to one bit line sense amplifier selected from among the plurality of bit line sense amplifiers.

### BRIEF DESCRIPTION OF THE DRAWINGS

Example embodiments will be more clearly understood from the following detailed description taken in conjunction with the accompanying drawings in which:

FIG. 1 is a block diagram showing a semiconductor device according to an example embodiment;

FIG. 2 is a schematic perspective view of a portion of a semiconductor device according to an example embodiment;

FIG. 3 is a schematic plan view of a portion of a semiconductor device according to an example embodiment;

FIG. 4 is a configuration diagram showing some components of a semiconductor device according to an example embodiment;

FIG. 5 is an enlarged diagram of a portion EX1 of FIG. 4;

FIGS. 6A, 6B, and 6C are diagrams showing some components of semiconductor devices according to some example embodiments;

FIG. 7 is a configuration diagram showing some components of a semiconductor device according to an example embodiment;

FIG. 8 is a configuration diagram showing some components of a semiconductor device according to an example embodiment;

FIG. 9 is an enlarged diagram of a portion EX2 of FIG. 8; and

FIG. 10 is a configuration diagram showing some components of a semiconductor device according to an example embodiment.

### DETAILED DESCRIPTION

Hereinafter, some example embodiments of the inventive concepts will be described in detail with reference to the attached drawings. The same reference numerals are used for the same components in the drawings, and repeated descriptions thereof are omitted.

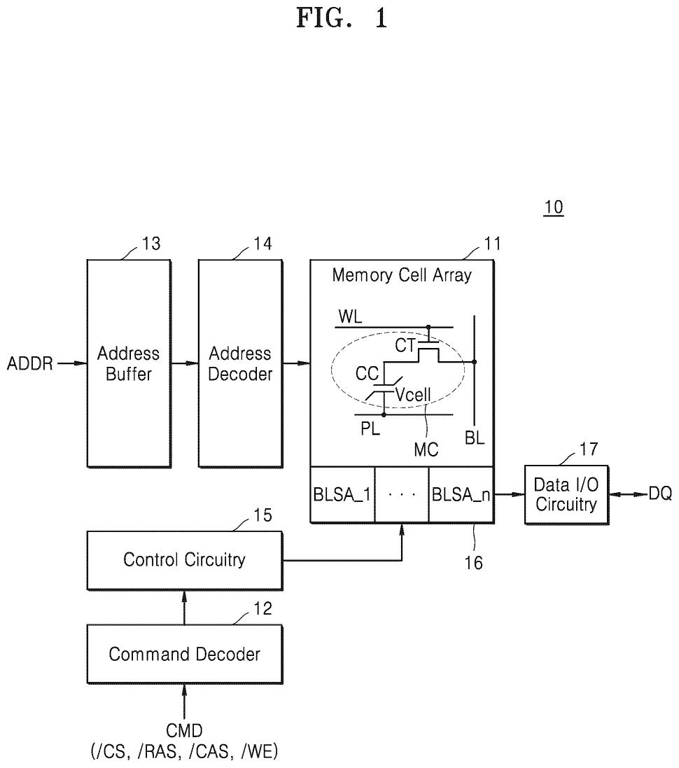

FIG. 1 is a block diagram showing a semiconductor device 10 according to an example embodiment.

Referring to FIG. 1, the semiconductor device 10 may include a memory cell array 11, a command decoder 12, an address buffer 13, an address decoder 14, control circuitry 15, a bit line sense amplifier (BLSA) 16, and data input/output circuitry 17.

The semiconductor device 10 may be implemented as a dynamic random access memory (DRAM) that senses a cell voltage Vcell stored in a memory cell MC as data.

The semiconductor device 10 may input and output data DQ in response to a command CMD and an address ADDR received from an external device (e.g., a central processing unit (CPU) or a memory controller).

The memory cell array 11 may include a plurality of memory cells MCs. The memory cell array 11 may include a plurality of word lines WLs, a plurality of bit lines BLs, and a plurality of plate lines PLs, which are connected to the memory cells MCs.

Each of the memory cells MCs may include a cell transistor CT and a cell capacitor CC. A gate terminal of the cell transistor CT may be connected to one of the word lines WLs of the memory cell array 11. A first terminal of the cell transistor CT may be connected to one of the bit lines BLs of the memory cell array 11. A second terminal of the cell transistor CT may be connected to the first terminal of the cell capacitor CC. The second terminal of the cell capacitor CC may be connected to one of the plate lines PLs of the memory cell array 11. The cell capacitor CC may store electric charges with a capacity corresponding to data.

The memory cell MC may store the cell voltage Vcell having a size specifying data in the cell capacitor CC.

The command decoder 12 may determine the input command CMD with reference to a chip select signal/CS, a row address strobe signal/RAS, a column address strobe signal/CAS, a write enable signal/WE, and the like, which are applied from an external device. The command decoder 12 may generate control signals corresponding to the command CMD. The command CMD may include an active command, a read command, a write command, a precharge command, and the like.

The address buffer 13 receives the address ADDR applied from an external device. The address ADDR includes a word line address that addresses some of the word lines WLs connected to the memory cell array 11, a bit line address that addresses some of the bit lines BLs connected to the memory cell array 11, and a plate line address that addresses some of the plate lines PLs connected to the memory cell array 11. The address buffer 13 may transmit each of the word line address, the bit line address, and the plate line address to the address decoder 14.

The address decoder 14 may include a word line decoder, a bit line decoder, and a plate line decoder, which respectively select a word line WL, a bit line BL, and a plate line PL of the memory cell MC, which are to be accessed in response to the received address ADDR.

The word line decoder may decode the word line address and activate the word line WL of the memory cell MC corresponding to the word line address. The bit line decoder may decode the bit line address and provide a bit line select signal BLS for selecting the bit line BL of the memory cell MC corresponding to the bit line address. The plate line decoder may decode the plate line address and provide a plate line select signal PLS that selects the plate line PL of the memory cell MC corresponding to the plate line address.

The control circuitry 15 may control the BLSA 16 according to control of the command decoder 12. The control circuitry 15 may control an operation of detecting the cell voltage Vcell of the memory cell MC by the BLSA 16. The control circuitry 15 may control the BLSA 16 to perform a precharge operation, a charge sharing operation, and a detection operation.

The BLSA 16 may include a plurality of sense amplifiers. The BLSA 16 may sense electric charges stored in the memory cell MC. The BLSA 16 may transmit the sensed data to the data input/output circuitry 17 to be output to the outside of the semiconductor device 10 through the data DQ pad(s).

The data input/output circuitry 17 may receive the data DQ to be written in the memory cells MCs from the outside and transmit the data DQ to the memory cell array 11. The data input/output circuitry 17 may output bit data sensed by the BLSA 16 to the outside as read data through the data (DQ) pad(s).

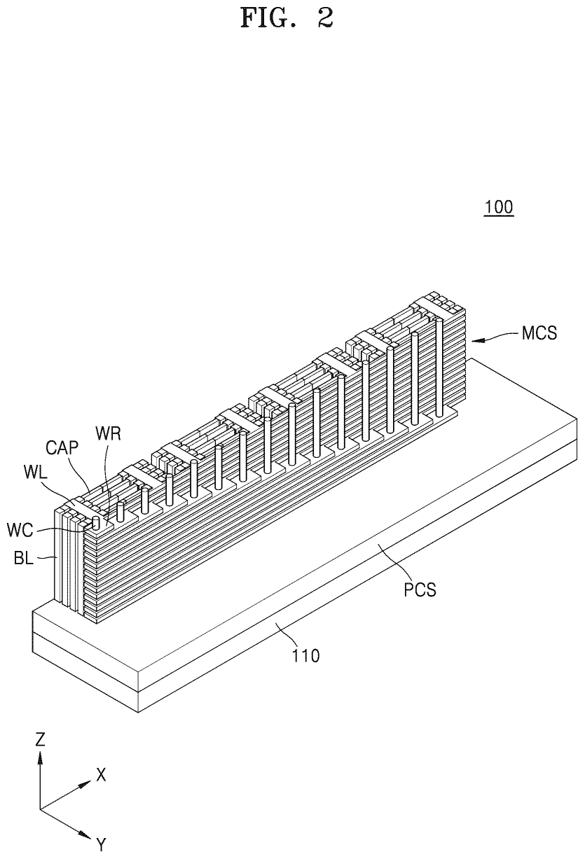

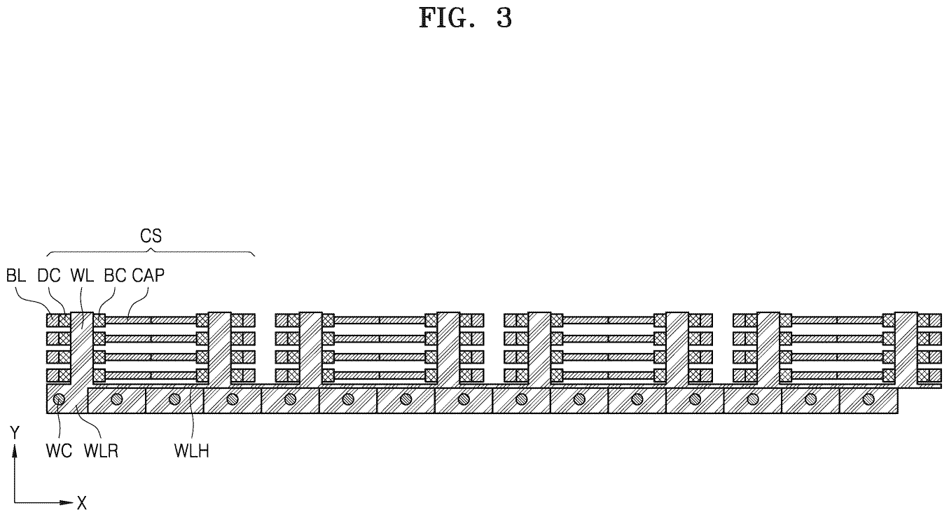

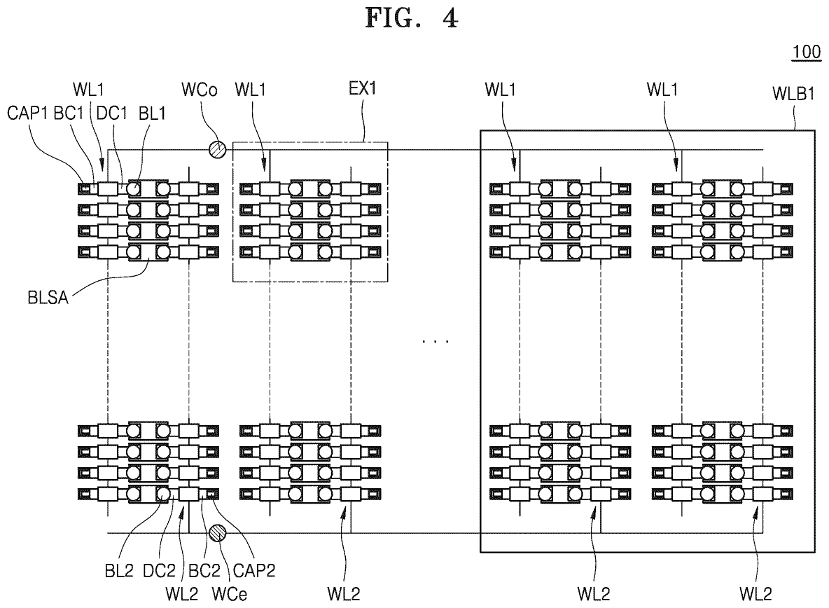

FIG. 2 is a schematic perspective view of a portion of a semiconductor device 100 according to an example embodiment. FIG. 3 is a schematic plan view of a portion of the semiconductor device 100 according to an example embodiment. Although FIGS. 2 and 3 show only a portion of a cell array structure MCS included in the semiconductor device 100 for convenience of description, the semiconductor device 100 may have a structure in which the structures illustrated in FIGS. 2 and 3 symmetrically overlap each other. For example, the semiconductor device 100 may include a plurality of word line contacts WC located on both sides of the plurality of word lines WL, as shown in the configuration diagram illustrated in FIG. 4.

Referring to FIGS. 2 and 3, the semiconductor device 100 may include a substrate 110, a peripheral circuit structure PCS, and the cell array structure MCS.

The substrate 110 may include a semiconductor material, for example, a Group IV semiconductor, Groups III to V compound semiconductors, or Groups II to VI oxide semiconductors. For example, a Group IV semiconductor may include silicon (Si), germanium (Ge), or silicon-germanium (SiGe). The substrate 110 may be provided as a bulk wafer or an epitaxial layer. In an some example embodiment, the substrate 110 may include a silicon-on-insulator (SOI) substrate, or a germanium-on-insulator (GeOI) substrate.

The peripheral circuit structure PCS may be provided on the substrate 110. The peripheral circuit structure PCS may include a peripheral circuit transistor located on the substrate 110, and a peripheral circuit wiring structure connecting the peripheral circuit transistors to each other or connecting the peripheral circuit transistor to components of the cell array structure MCS.

The peripheral circuit transistor may constitute a plurality of peripheral circuits. The plurality of peripheral circuits including the peripheral circuit transistors may include the various circuits described with reference to FIG. 1. For example, the plurality of peripheral circuits may include the command decoder 12, the address buffer 13, the address decoder 14, the control circuitry 15, the BLSA 16, and the data input/output circuitry 17 illustrated in FIG. 1.

The cell array structure MCS may be located on the peripheral circuit structure PCS. The cell array structure MCS may include a plurality of stacked structures CS, and each of the plurality of stacked structures CS may include the plurality of word lines WL, the plurality of bit lines BL, and a plurality of capacitor structures CAP. The plurality of stacked structures CS may be arranged apart from each other in a first horizontal direction (X direction) on the peripheral circuit structure PCS.

The plurality of word lines WL may be stacked in a vertical direction (Z direction) on the peripheral circuit structure PCS. Each of the plurality of word lines WL stacked in the vertical direction (Z direction) may be arranged apart from each other in the vertical direction (Z direction). Each of the plurality of word lines WL may extend in a second horizontal direction (Y direction). The plurality of word lines WL may correspond to the plurality of word lines WL included in the memory cell array 11 of the semiconductor device 10 illustrated in FIG. 1.

The plurality of capacitor structures CAP may be located between the plurality of word lines WL arranged apart in the first horizontal direction (X direction). The plurality of capacitor structures CAP may extend in the first horizontal direction (X direction) between the plurality of word lines WL. The plurality of capacitor structures CAP may be stacked in the vertical direction (Z direction) between the plurality of word lines WL. The plurality of capacitor structures CAP may correspond to the plurality of cell capacitors CC included in the memory cell array 11 of the semiconductor device 10 illustrated in FIG. 1.

The plurality of capacitor structures CAP may include a first electrode (not shown), a second electrode (not shown) surrounding the first electrode, and a dielectric film (not shown) located between the first electrode and the second electrode. For example, the first electrode may have an empty cylinder shape, and the second electrode may fill the inside of the first electrode.

The first electrode and the second electrode may each include at least one of a metal material such as titanium, tantalum, tungsten, copper, or aluminum, a conductive metal nitride such as titanium nitride or tantalum nitride, or a doped semiconductor material such as doped silicon or doped germanium. The dielectric film may also include a high dielectric constant material. The high dielectric constant material may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

A BC may be located between each of the plurality of word lines WL and a corresponding one of the plurality of capacitor structures CAP. One side of the BC may be in contact with one word line WL selected from among the plurality of word lines WL, and the other side of the BC, which faces the one side of the BC in the first horizontal direction (X direction), may be in contact with one capacitor structure CAP selected from among the plurality of capacitor structures CAP. The selected word line WL and the selected capacitor structure CAP may be connected to each other by the BC. The BC may refer to, for example, a source/drain region located between each of the plurality of word lines WL and a corresponding one of the plurality of capacitor structures CAP.

The plurality of bit lines BL may be arranged apart from the plurality of capacitor structures CAP in the first horizontal direction (X direction) with the plurality of word lines WL therebetween. Each of the plurality of bit lines BL may extend in the vertical direction (Z direction). The plurality of bit lines BL may each be arranged in the second horizontal direction (Y direction). The plurality of bit lines BL may correspond to the plurality of bit lines BL included in the memory cell array 11 of the semiconductor device 10 illustrated in FIG. 1.

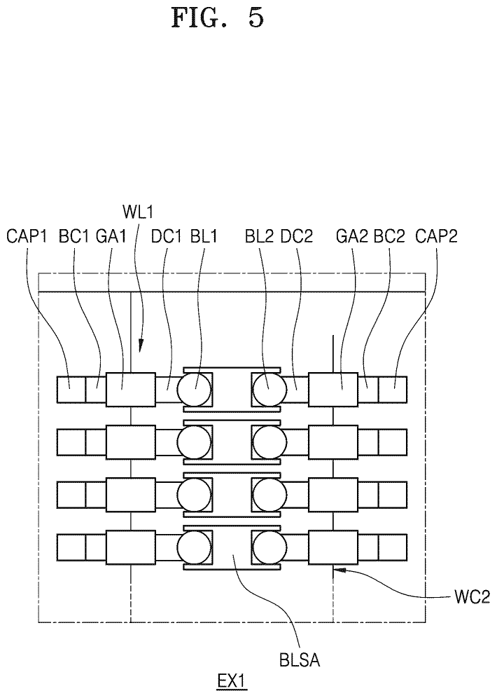

A cell transistor (not shown) may be formed in a region in which the plurality of bit lines BL and the plurality of word lines WL intersect with each other. The cell transistor may correspond to the cell transistor CT included in the memory cell array 11 of the semiconductor device 10 illustrated in FIG. 1. For example, the cell transistor may include gates GA1 and GA2 illustrated in FIG. 5 and a gate dielectric film (not shown) surrounded by the gates GA1 and GA2. The cell transistor may constitute a memory cell of the cell array structure MCS with the capacitor structure CAP.

A DC may be located between each of the plurality of word lines WL and a corresponding one of the plurality of bit lines BL. One side of the DC may be in contact with one word line WL selected from among the plurality of word lines WL, and the other side of the DC, which faces the side of the DC in the first horizontal direction (X direction), may be in contact with one bit line BL selected from among the plurality of bit lines BL. The selected word line WL and the selected bit line BL may be connected to each other by the DC. The DC may refer to, for example, a source/drain region located between each of the plurality of word lines WL and a corresponding one of the plurality of bit lines BL.

A plurality of first horizontal extensions WLH may be located at one side of the plurality of word lines WL, respectively. The plurality of first horizontal extensions WLH may be stacked at one side of the plurality of word lines WL in the vertical direction (Z direction), respectively. The plurality of stacked first horizontal extensions WLH may be located at the same vertical level as the plurality of stacked word lines WL, respectively. For example, a first horizontal extension WLH located at the uppermost end of the plurality of first horizontal extensions WLH may be located at the same vertical level as the word line WL located at the uppermost end of the plurality of word lines WL, and a first horizontal extension WLH located at the lowermost end of the plurality of first horizontal extensions WLH may be located at the same vertical level as the word line WL located at the lowermost end of the plurality of word lines WL. The plurality of first horizontal extensions WLH may extend in a first horizontal direction (X direction).

The word lines WL located at the same vertical level from among the plurality of word lines WL included in each of the plurality of stacked structures CS may be connected to the first horizontal extension WLH. For example, the word lines WL located at the uppermost end of the plurality of word lines WL included in each of the plurality of stacked structures CS may be connected to the first horizontal extension WLH located at the uppermost end of the plurality of first horizontal extensions WLH.

A plurality of second horizontal extensions WLR may be located at one side of the plurality of first horizontal extensions WLH, respectively. The plurality of second horizontal extensions WLR may be regions in which the plurality of word line contacts WC are located. The plurality of second horizontal extensions WLR may be stacked at one side of the plurality of first horizontal extensions WLH in the vertical direction (Z direction), respectively. The plurality of stacked second horizontal extensions WLR may be located at the same vertical level as the plurality of stacked first horizontal extensions WLH, respectively. For example, a second horizontal extension WLR located at the uppermost end of the plurality of second horizontal extensions WLR may be located at the same vertical level as the first horizontal extension WLH located at the uppermost end of the plurality of first horizontal extensions WLH, and the second horizontal extension WLR located at the lowermost end of the plurality of second horizontal extensions WLR may be located at the same vertical level as the first horizontal extension WLH located at the lowermost end of the plurality of first horizontal extensions WLH.

The plurality of second horizontal extensions WLR may extend to have a reduced length in the first horizontal direction (X direction) away from an upper surface of the substrate 110. That is, the plurality of second horizontal extensions WLR may have a step shape.

The plurality of word line contacts WC may be located at the plurality of second horizontal extensions WLR, respectively. One word line contact WC located at one second horizontal extension WLR selected from among the plurality of second horizontal extensions WLR may be connected to word lines WL located at the same vertical level from among the plurality of word lines WL that are included in the plurality of stacked structures CS, respectively. For example, the word lines WL located at the uppermost end of the plurality of word lines WL that are included in the plurality of stacked structures CS, respectively, may be connected to one first horizontal extension WLH located at the uppermost end of the plurality of first horizontal extensions WLH and one second horizontal extension WLR located at the uppermost end of the plurality of second horizontal extensions WLR, and one word line contact WC located at one second horizontal extension WLR located at the uppermost end may be connected to the word lines WL located at the uppermost end of the plurality of word lines WL that are included in the plurality of stacked structures CS through one second horizontal extension WLR located at the uppermost end.

The semiconductor device 100 according to some example embodiments may include the first horizontal extension WLH and the second horizontal extension WLR connected to the word lines WL located at the same vertical levels from among the plurality of word lines WL included in each of the plurality of stacked structures CS, and may include the word line contact WC located on the second horizontal extension WLR and connected to the word lines WL located at the same vertical level from among the plurality of word lines WL. Accordingly, each of the word lines WL located at the same vertical level from among the plurality of word lines WL included in each of the plurality of stacked structures CS may not have a separate word line contact, and thus, a space for forming the word line contact may be saved. Accordingly, more memory cells may be arranged in the same size, and thus the integration of the semiconductor device 100 may be improved.

Hereinafter, some components of the semiconductor device 100 will be described in more detail with reference to FIGS. 4 and 5.

FIG. 4 is a configuration diagram showing some components of the semiconductor device 100 according to an example embodiment. FIG. 5 is an enlarged diagram of a portion EX1 of FIG. 4.

Referring to FIGS. 4 and 5, the semiconductor device 100 may include a plurality of first word lines WL1 and a plurality of second word lines WL2, which extend in a first direction. Here, the plurality of first word lines WL1 and the plurality of second word lines WL2 may be word lines included in the plurality of word lines WL (refer to FIGS. 2 and 3).

The plurality of stacked first word lines WL1 may be arranged in a plurality of columns to be apart from each other in the first horizontal direction (X direction), and the plurality of stacked second word lines WL2 may be arranged in a plurality of columns to be apart from each other in the first horizontal direction (X direction). The plurality of first word lines WL1 and the plurality of second word lines WL2 may be alternately arranged in a second direction perpendicular to the first direction. For example, when four adjacent word lines of a plurality of word lines included in the semiconductor device 100 are considered as one word line array unit WLB1, word lines located first and third of the one word line array unit may correspond to the first word line WL1, and word lines placed second and fourth in the one word line array unit may correspond to the second word line WL2. In some example embodiments, the first word lines WL1 and the plurality of second word lines WL2 may be located at the same vertical level.

The plurality of first word lines WL1 may be connected to a first word line contact WCo, and the plurality of second word lines WL2 may be connected to a second word line contact WCe. Here, the second word line contact WCe may correspond to the plurality of word line contacts WC (refer to FIGS. 2 and 3), and the first word line contact WCo may correspond to other plurality of word line contacts arranged apart from the plurality of word line contacts WC (e.g., the second word line contact WCe) in the second horizontal direction (Y direction) with the plurality of word lines WL being located between the first word line contact WCo and the plurality of word line contacts WC (e.g., the second word line contact WCe).

A plurality of first bit lines BL1 and a plurality of first capacitor structures CAP1 may be located on both sides of the plurality of first word lines WL1, respectively, and a plurality of second bit lines BL2 and a plurality of second capacitor structures CAP2 may be located on both sides of the plurality of second word lines WL2, respectively. A first DC DC1 may be located between each of the plurality of first word lines WL1 and the first bit line BL1, a first BC BC1 may be located between each of the plurality of first word lines WL1 and the first capacitor structure CAP1, a second DC DC2 may be located between each of the plurality of second word lines WL2 and the second bit line BL2, and a second BC BC2 may be located between each of the plurality of second word lines WL2 and the second capacitor structure CAP2. Here, the first bit line BL1 and the second bit line BL2 may correspond to the plurality of bit lines BL (refer to FIGS. 2 and 3), the first capacitor structure CAP1 and the plurality of second capacitor structures CAP2 may correspond to the plurality of capacitor structures CAP (refer to FIGS. 2 and 3), the first DC DC1 and the second DC DC2 may correspond to the DC (refer to FIGS. 2 and 3), and the first BC BC1 and the second BC BC2 may correspond to the BC (refer to FIGS. 2 and 3).

The plurality of first bit lines BL1 and the plurality of first capacitor structure CAP1 may be arranged apart from each other in an extension direction of the first word line WL1, and the plurality of second bit lines BL2 and the plurality of second capacitor structures CAP2 may be arranged apart from each other in an extension direction of the second word line WL2.

The first bit line BL1 and one second bit line BL2 may have a complementary relationship. Accordingly, the first bit line BL1 may be referred to as a bit line, and the second bit line BL2 may be referred to as a complementary bit line.

A portion of the plurality of first word lines WL1, which intersects with the first bit line BL1, may be referred to as a first gate GA1, and a portion of the plurality of second word lines WL2, which intersects with the second bit line BL2, may be referred to as a second gate GA2. The first gate GA1 may constitute a cell transistor of a memory cell in a region in which the plurality of first word lines WL1 and the first bit line BL1 intersect with each other, and the second gate GA2 may constitute a cell transistor of a memory cell in a region in which the plurality of second word lines WL2 and the second bit line BL2 intersect with each other.

One first bit line BL1 and one second bit line BL2 adjacent to each other may be connected to one BLSA. That is, when the semiconductor device 100 includes n first bit lines BL1 and n second bit lines BL2, the semiconductor device 100 may include n BLSAs. The BLSA may be included in a peripheral circuit formed in the peripheral circuit structure PCS (refer to FIG. 2). The BLSA may correspond to the BLSA 16 illustrated in FIG. 1. The plurality of bit lines BL1 and BL2 are not connected to one BLSA and one first bit line BL1 and one second bit line BL2 adjacent to each other are connected to one BLSA, and thus when the plurality of first word lines WL1 of the semiconductor device 100 are connected to one first word line contact WCo and the plurality of second word lines WL2 are connected to one second word line contact WCe, addressing of the memory cell array 11 (refer to FIG. 1) may also be smoothly performed.

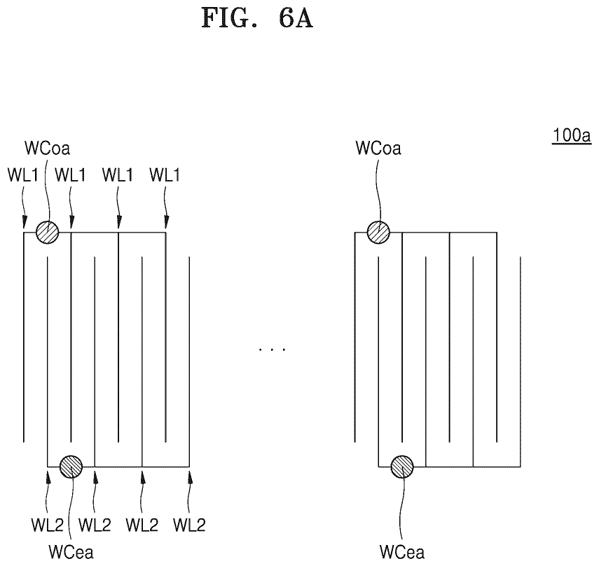

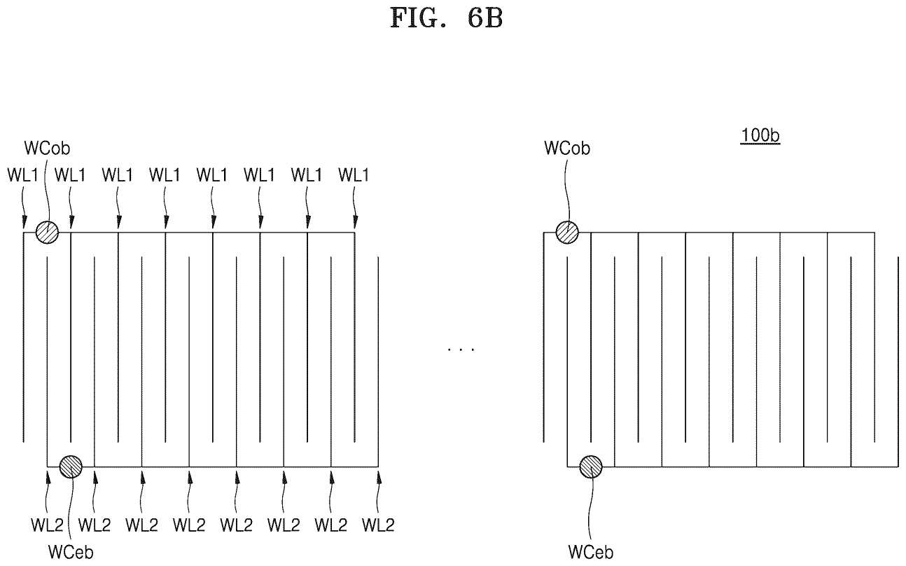

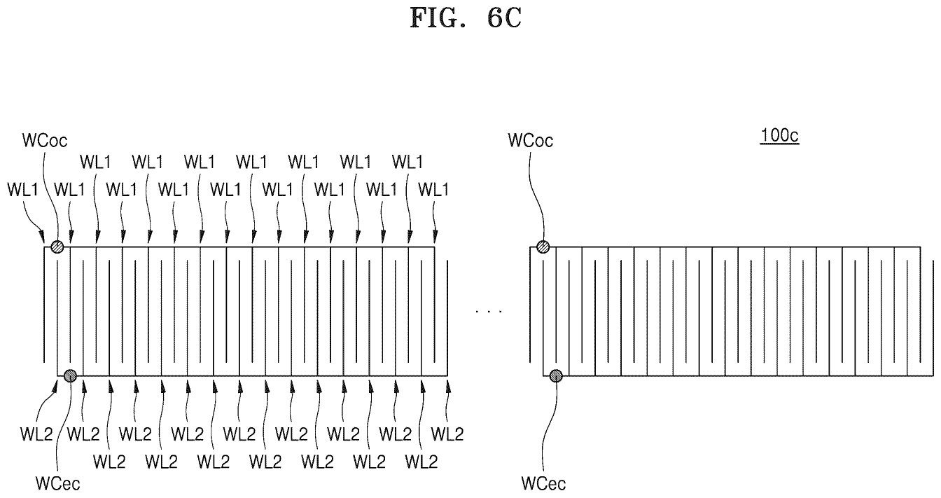

FIGS. 6A, 6B, and 6C are diagrams showing some components of semiconductor devices 100a, 100b, and 100c according to some example embodiments. Components of each of the semiconductor device 100a, 100b, and 100c illustrated in FIGS. 6A, 6B, and 6C are similar to the components of the semiconductor device 100 described with reference to FIGS. 2 to 5, and thus will be described in terms of differences therefrom will be described hereinafter.

Referring to FIG. 6A, the semiconductor device 100a may include a plurality of first word line contacts WCoa and a plurality of second word line contacts WCea and have the same configuration as the semiconductor device 100 illustrated in FIGS. 2 to 5 except that four first word lines WL1 selected from among the plurality of first word lines WL1 are connected to a corresponding one of the plurality of first word line contacts WCo, and four second word lines WL2 selected from among the plurality of second word lines WL2 are connected to a corresponding one of the plurality of second word line contacts WCea. That is, when the semiconductor device 100a includes 16n first word lines WL1 and 16n second word lines WL2, the semiconductor device 100a may include 4n first word line contacts WCoa and n second word line contacts WCea.

Referring to FIG. 6B, the semiconductor device 100b may include a plurality of first word line contacts WCob and a plurality of second word line contacts WCeb and have the same configuration as the semiconductor device 100 illustrated in FIGS. 2 to 5 except that eight first word lines WL1 selected from among the plurality of first word lines WL1 are connected to a corresponding one of the plurality of first word line contacts WCob, and eight second word lines WL2 selected from among the plurality of second word lines WL2 are connected to a corresponding one of the plurality of second word line contacts WCeb. That is, when the semiconductor device 100b includes 16n first word lines WL1 and 16n second word lines WL2, the semiconductor device 100b may include 2n first word line contacts WCob and 2n second word line contacts WCeb.

Referring to FIG. 6C, the semiconductor device 100c may include a plurality of first word line contacts WCoc and a plurality of second word line contacts WCec and have the same configuration as the semiconductor device 100 illustrated in FIGS. 2 to 5 except that 16 first word lines WL1 selected from among the plurality of first word lines WL1 are connected to a corresponding one of the plurality of first word line contacts WCoc, and 16 second word lines WL2 selected from among the plurality of second word lines WL2 are connected to a corresponding one of the plurality of second word line contacts WCec. That is, when the semiconductor device 100c includes 16n first word lines WL1 and 16n second word lines WL2, the semiconductor device 100c may include n first word line contacts WCoc and 2n second word line contacts WCec.

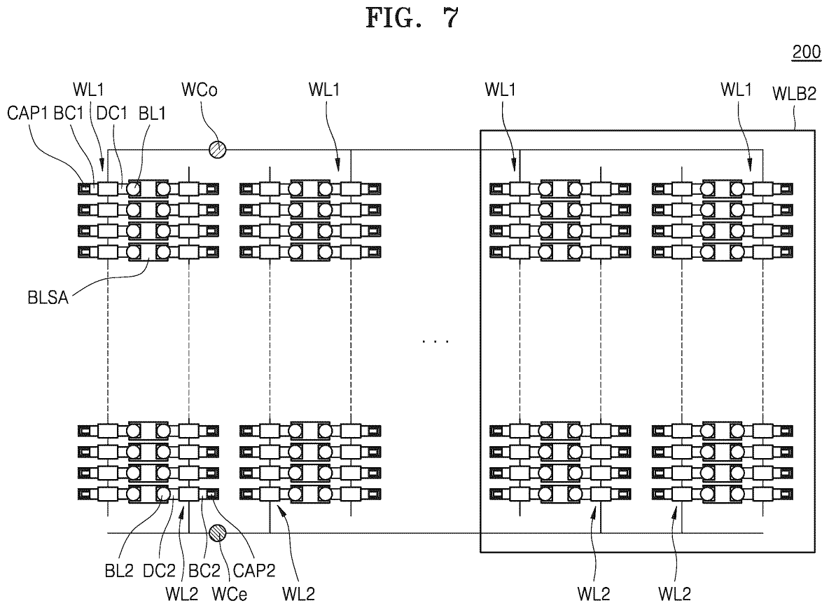

FIG. 7 is a configuration diagram showing some components of a semiconductor device 200 according to an example embodiment. Components of the semiconductor device 200 illustrated in FIG. 7 are similar to the components of the semiconductor device 100 described with reference to FIGS. 2 to 5, and thus will be described in terms of differences therefrom will be described hereinafter.

Referring to FIG. 7, the semiconductor device 200 may have the same configuration as the semiconductor device 100 illustrated in FIGS. 2 to 5 except that an arrangement of the plurality of first word lines WL1 and the plurality of second word lines WL2 is different from an arrangement of the plurality of first word lines WL1 and the plurality of second word lines WL2 of the semiconductor device 100 illustrated in FIGS. 2 to 5.

When four adjacent word lines of a plurality of word lines included in the semiconductor device 200 are considered as one word line array unit WLB2, two word lines located at an edge of the one word line array unit may correspond to the second word line WL2, and two word lines located at a central portion may correspond to the first word line WL1.

However, the arrangement of the first word line WL1 and the second word line WL2 of the semiconductor device is not limited to the arrangement described above, and for example, differently from the semiconductor device 100 illustrated in FIG. 4 and the arrangement illustrated in FIG. 7, when four adjacent word lines from among a plurality of word lines included in the semiconductor device are considered as one word line array unit, two word lines located first and second of the one first line array unit may correspond to the first word line WL1, and two word lines located third and fourth may correspond to the second word line WL2.

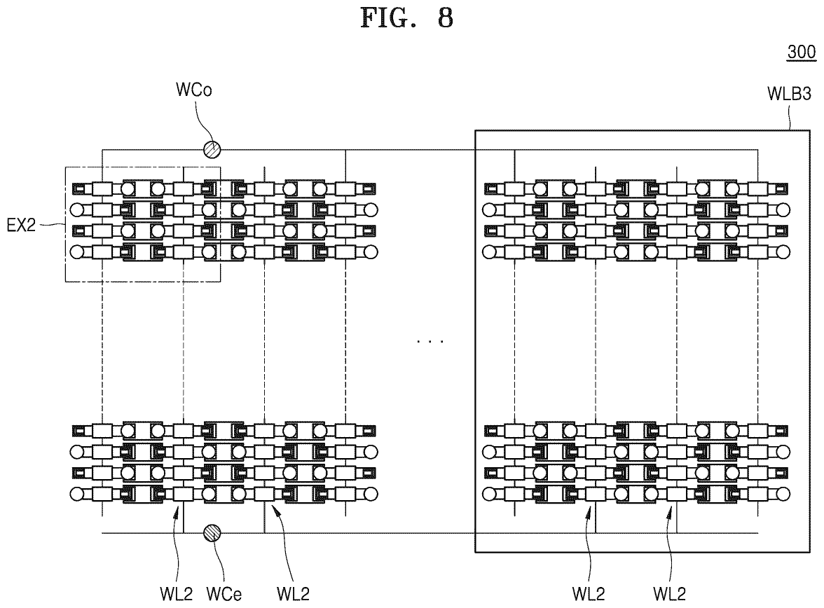

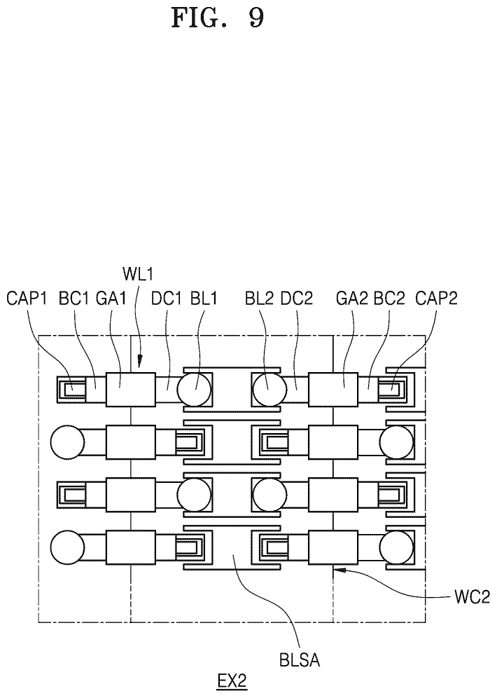

FIG. 8 is a configuration diagram showing some components of a semiconductor device 300 according to an example embodiment. FIG. 9 is an enlarged diagram of a portion EX2 of FIG. 8. Components the semiconductor device 300 illustrated in FIGS. 8 and 9 are similar to the components of the semiconductor device 100 described with reference to FIGS. 2 to 5, and thus will be described in terms of differences therefrom will be described hereinafter.

Referring to FIGS. 8 and 9, the semiconductor device 300 have the same configuration except that an arrangement of the plurality of first word lines WL1 and the plurality of second word lines WL2 of the semiconductor device 300 is different from an arrangement of the plurality of first word lines WL1 and the plurality of second word lines WL2 of the semiconductor device 100 and an arrangement of the bit lines BL1 and BL2 and the capacitor structures CAP1 and CAP2 is different from an arrangement of the bit lines BL1 and BL2 and the capacitor structures CAP1 and CAP2 of the semiconductor device 100 illustrated in FIGS. 2 to 5.

When four word lines adjacent to each other from among the plurality of word lines included in the semiconductor device 300 are considered as one word line array unit WLB3, an arrangement of the first word line WL1 and the second word line WL2 of the semiconductor device 300 may substantially the same as an arrangement of the first word line WL1 and the second word line WL2 of the semiconductor device 200 illustrated in FIG. 7. However, the arrangement of the first word line WL1 and the second word line WL2 of the semiconductor device 300 is not limited to the arrangement described above, and for example, unlike arrangements illustrated in FIGS. 8 and 9, an arrangement of the first word line WL1 and the second word line WL2 of the semiconductor device 300 may be substantially the same as the arrangement of the first word line WL1 and the second word line WL2 of the semiconductor device 100 illustrated in FIGS. 4 and 5.

At least some of the plurality of first bit lines BL1 of the semiconductor device 300 may be located on one side of the first word line WL1, and the other some of the plurality of first bit lines BL1 except for the at least some of the plurality of first bit lines BL1 may be located on the other side of the first word line WL1 that faces the one side of the first word line WL1. For example, the plurality of first bit lines BL1 may be arranged in a zigzag form in the extension direction of the first word line WL1. According to the arrangement of the plurality of first bit lines BL1, the plurality of first capacitor structures CAP1 may also be arranged similarly to the plurality of first bit lines BL1.

At least some of the plurality of bit lines BL2 of the semiconductor device 300 may be located on one side of the second word line WL2, and the other some of the plurality of bit lines BL2 except for the at least some of the plurality of bit lines BL2 may be located on the other side of the second word line WL2 that faces the one side of the second word line WL2. For example, the plurality of second bit lines BL2 may be arranged in a zigzag form in the extension direction of the second word line WL2. According to the arrangement of the plurality of second bit lines BL2, the plurality of second capacitor structures CAP2 may also be arranged similarly to the plurality of second bit lines BL2.

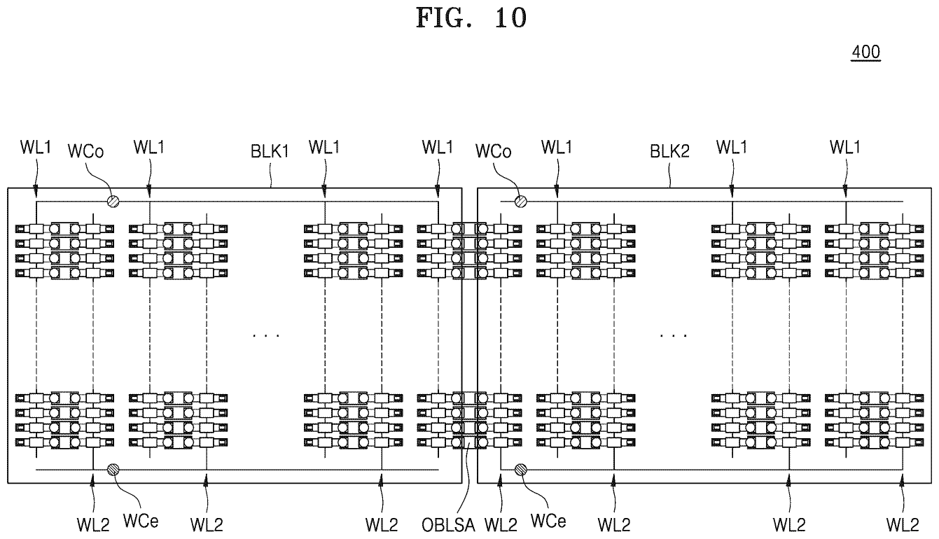

FIG. 10 is a configuration diagram showing some components of a semiconductor device according to an example embodiment. Components of a semiconductor device 400 illustrated in FIG. 10 are similar to the components of the semiconductor device 100 described with reference to FIGS. 2 to 5, and thus will be described in terms of differences therefrom will be described hereinafter.

Referring to FIG. 10, the semiconductor device 400 may have the same configuration as the semiconductor device 100 illustrated in FIGS. 2 to 5 except that a portion of the first bit line BL1 included in a first memory cell block BLK1 and a portion of the second bit line BL2 included in a second memory cell block BLK2 are connected to a bit line sense amplifier OBLSA. That is, the semiconductor device 400 may have an open bit line structure.

A separation pattern (not shown) may be located between the first memory cell block BLK1 and the second memory cell block BLK2 of the semiconductor device 400. The separation pattern may include, for example, an insulating material. The separation pattern may electrically separate the first memory cell block BLK1 and the second memory cell block BLK2 from each other.

The first memory cell block BLK1 and the second memory cell block BLK2 of the semiconductor device 400 may constitute the cell array structure MCS (refer to FIG. 2).

The first memory cell block BLK1 and the second memory cell block BLK2 of the semiconductor device 400 may be arranged in the same manner as the configurations of the semiconductor device 100 illustrated in FIGS. 4 and 5. For example, the first memory cell block BLK1 and the second memory cell block BLK2 of the semiconductor device 400 may each include the plurality of first word lines WL1 and the plurality of second word lines WL2 that are arranged alternately in one direction. However, the technical spirits of the inventive concepts are not limited thereto. In some example embodiments, the first memory cell block BLK1 of the semiconductor device 400 may be located in the same manner as the configurations of the semiconductor device 100 illustrated in FIGS. 4 and 5 and the second memory cell block BLK2 may be located in the same manner as the configurations of the semiconductor device 100 illustrated in FIG. 7.

The number of the first word lines WL1 included in the first memory cell block BLK1 may be one more than the number of the second word lines WL2 included in the first memory cell block BLK1. For example, the number of the first word lines WL1 included in the first memory cell block BLK1 may be n+1 and the number of the second word lines WL2 included in the first memory cell block BLK1 may be n. In this case, the number of columns of the first word lines WL1 located at one side of the first word line WL1 in the extension direction of the first word line WL1 may be n+1, and the number of columns of the second word line WL2 located at one side of the second word line WL2 in the extension direction of the second word line WL2 may be n.

In contrast, the number of the second word lines WL2 included in the second memory cell block BLK2 may be one more than the number of the first word line WL1 included in the second memory cell block BLK2. For example, the number of the first word lines WL1 included in the first memory cell block BLK1 may be n and the number of the second word lines WL2 included in the second memory cell block BLK2 may be n+1. In this case, the number of columns of the first word lines WL1 located at one side of the first word line WL1 in the extension direction of the first word line WL1 may be n, and the number of columns of the second word line WL2 located at one side of the second word line WL2 in the extension direction of the second word line WL2 may be n+1.

The first bit line BL1 and the second bit line BL2, which face each other in the first memory cell block BLK and the second memory cell block BLK, may be connected to one BLSA. In this case, in the first memory cell block BLK1, the number of columns of the first bit line BL1 is one more than that of the second bit line BL2, and thus one of the columns of the first bit line BL1 may not be connected to the second bit line BL2 and one BLSA in the first memory cell block BLK1. In the second memory cell block BLK2, the number of columns of the second bit line BL2 is one more than that of the first bit line BL1, and thus one of the columns of the second bit line BL2 may not be connected to the first bit line BL1 and one BLSA in the second memory cell block BLK2.

A column of one first bit line BL1, which is not connected to the BLSA within the first memory cell block BLK1 from among columns of the first bit line BL1 included in the first memory cell block BLK1, and a column of one second bit line BL2, which is not connected to the BLSA in the second memory cell block BLK2 from among the second bit line BL2 included in the second memory cell block BLK2, may be connected to the OBLSA, and thus the semiconductor device 400 may have an open bit line structure.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As above, some example embodiments have been disclosed in the drawings and specification. Although some example embodiments have been described in this specification using certain terms, this is used for the purpose of explaining the technical spirit of the inventive concepts and is not used to limit the meaning or scope of the inventive concepts as set forth in the claims. Therefore, those skilled in the art will understand that various modifications and other equivalent embodiments are possible therefrom. Therefore, the true technical protection scope of the inventive concepts needs to be determined by the technical spirit and scope of the attached claims.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate;
a plurality of word lines stacked on the substrate;
a plurality of bit lines at one side of the plurality of word lines, the plurality of bit lines extending in a vertical direction perpendicular to an upper surface of the substrate;
a plurality of capacitor structures at another side of the plurality of word lines, the another side of the plurality of word lines facing the one side of the plurality of word lines, the plurality of capacitor structures extending in a first horizontal direction parallel to the upper surface of the substrate;
a plurality of first horizontal extensions extending in the first horizontal direction and stacked on the substrate; and
a plurality of second horizontal extensions connected to the plurality of first horizontal extensions, respectively,
wherein a group of word lines at a certain vertical level from among the plurality of word lines are connected to one first horizontal extension at a same vertical level as the group of word lines from among the plurality of first horizontal extensions, and
a word line contact is on one second horizontal extension connected to the first horizontal extension from among the plurality of second horizontal extensions.

2. The semiconductor device of claim 1, wherein the plurality of first horizontal extensions and the plurality of second horizontal extensions each are at a same vertical level as the plurality of word lines.

3. The semiconductor device of claim 1, wherein the plurality of second horizontal extensions have a reduced length in the first horizontal direction away from the upper surface of the substrate.

4. The semiconductor device of claim 1, wherein
the word line contact includes a plurality of word line contacts, and
the plurality of word line contacts are on the plurality of second horizontal extensions, respectively, and are spaced apart from each other in the first horizontal direction.

5. The semiconductor device of claim 1, wherein the group of word lines are connected to the one first horizontal extension and are connected to the word line contact through the one second horizontal extension.

6. A semiconductor device comprising:
a substrate;
a peripheral circuit structure on the substrate, the peripheral circuit structure including a plurality of bit line sense amplifiers;
a plurality of first word lines stacked on the substrate;
a plurality of second word lines stacked on the substrate, the plurality of second word lines being apart from the plurality of first word lines in a first horizontal direction parallel to an upper surface of the substrate;
a plurality of first bit lines at one side of the plurality of first word lines, the plurality of first bit lines extending in a vertical direction perpendicular to the upper surface of the substrate;
a plurality of first capacitor structures at another side of the plurality of first word lines, the another side of the plurality of first word lines facing the one side of the plurality of first word lines, the plurality of first capacitor structures extending in the first horizontal direction;
a plurality of second bit lines at one side of the plurality of second word lines adjacent to the one side of the plurality of first word lines, the plurality of second bit lines extending in the vertical direction;
a plurality of second capacitor structures at another side of the plurality of second word lines, the another side of the plurality of second word lines facing the one side of the plurality of second word lines, the plurality of second capacitor structures extending in the first horizontal direction;
a plurality of first horizontal extensions extending in the first horizontal direction and stacked on the substrate; and
a plurality of second horizontal extensions connected to the plurality of first horizontal extensions, respectively,
wherein a group of first word lines at a certain vertical level from among the plurality of first word lines are connected to one first horizontal extension at a same vertical level as the group of first word lines from among the plurality of first horizontal extensions,
at least one first word line contact is on one second horizontal extension connected to the first horizontal extension from among the plurality of second horizontal extensions,
a group of second word lines at a certain vertical level from among the plurality of second word lines are connected to another first horizontal extension at a same vertical level as the second word lines from among the plurality of first horizontal extensions, and
at least one second word line contact is on another second horizontal extension connected to the another first horizontal extension from among the plurality of first horizontal extensions.

7. The semiconductor device of claim 6, wherein
the plurality of first word lines are arranged in a plurality of columns to be apart from each other in the first horizontal direction, and
the group of first word lines are connected to the one first horizontal extension and are connected to the one first word line contact through the one second horizontal extension.

8. The semiconductor device of claim 6, wherein
the plurality of second word lines are arranged in a plurality of columns to be apart from each other in the first horizontal direction, and
the group of second word lines are connected to the another first horizontal extension and are connected to the one second word line contact through the another second horizontal extension.

9. The semiconductor device of claim 6, wherein one first bit line selected from among the plurality of first bit lines and one second bit line selected from among the plurality of second bit lines and facing the one first bit line in the first horizontal direction are connected to one bit line sense amplifier selected from among the plurality of bit line sense amplifiers.

10. The semiconductor device of claim 6, wherein the plurality of first word lines and the plurality of second word lines are alternately arranged in the first horizontal direction.

11. The semiconductor device of claim 6, wherein
the first word line contact includes a plurality of first word line contacts,
the plurality of first word lines are in a plurality of columns and apart from each other in the first horizontal direction, and
at least two first word lines from among the plurality of first word lines at a same vertical level are connected to a corresponding one of the plurality of first word line contacts.

12. The semiconductor device of claim 6, wherein
the second word line contact includes a plurality of second word line contacts,
the plurality of second word lines are in a plurality of columns and apart from each other in the first horizontal direction, and
at least two second word lines from among the plurality of second word lines at a same vertical level are connected to a corresponding one of the plurality of second word line contacts.

13. The semiconductor device of claim 9, wherein, in a word line array unit including four word lines that are apart from each other in a first horizontal direction, the plurality of first word lines include first and fourth word lines in the first horizontal direction, and the plurality of second word lines include second and third word lines in the first horizontal direction.

14. The semiconductor device of claim 9, wherein the plurality of first bit lines and the plurality of first capacitor structures are arranged in a line in a second horizontal direction intersecting with the first horizontal direction on both sides of the plurality of first word lines, respectively.

15. The semiconductor device of claim 9, wherein the plurality of second bit lines and the plurality of second capacitor structures are arranged in a line in a second horizontal direction intersecting with the first horizontal direction on both sides of the plurality of second word lines.

16. The semiconductor device of claim 9, wherein the plurality of first bit lines and the plurality of first capacitor structures are arranged in a zigzag form in a second horizontal direction intersecting with the first horizontal direction on both sides of the plurality of first word lines.

17. The semiconductor device of claim 9, wherein the plurality of second bit lines and the plurality of second capacitor structures are arranged in a zigzag form in a second horizontal direction intersecting with the first horizontal direction on both sides of the plurality of second word lines.

18. A semiconductor device comprising:
a substrate;
a peripheral circuit structure on the substrate, the peripheral circuit structure including a plurality of bit line sense amplifier; and
a cell array structure on the peripheral circuit structure, the cell array structure including a first memory cell block and a second memory cell block,
wherein each of the first memory cell block and the second memory cell block includes,
a plurality of first word lines stacked on the substrate,
a plurality of second word lines stacked on the substrate and apart from the plurality of first word lines in a first horizontal direction parallel to an upper surface of the substrate,
a plurality of first bit lines at one side of the plurality of first word lines, the plurality of first bit lines extending in a vertical direction perpendicular to the upper surface of the substrate,
a plurality of second bit lines at one side of the plurality of second word lines adjacent to the one side of the plurality of first word lines, the plurality of second bit lines extending in the vertical direction,
a plurality of first horizontal extensions extending in the first horizontal direction and stacked on the substrate,
a plurality of second horizontal extensions connected to the plurality of first horizontal extensions, respectively,
a group of first word lines at a certain vertical level from among the plurality of first word lines are connected to one first horizontal extension at a same vertical level as the group of first word lines from among the plurality of first horizontal extensions,
at least one first word line contact is on a second horizontal extension connected to the one first horizontal extension,
a group of second word lines at a certain vertical level from among the plurality of second word lines are connected to another first horizontal extension at a same vertical level as the group of second word lines from among the plurality of first horizontal extensions, and
at least one second word line contact is on another second horizontal extension connected to the another first horizontal extension, and
a first word line adjacent to the second memory cell block from among the plurality of first word lines of the first memory cell block and a first word line adjacent to the first memory cell block from among the plurality of second word lines of the second memory cell block are connected to one bit line sense amplifier selected from among the plurality of bit line sense amplifiers.

19. The semiconductor device of claim 18, wherein
the plurality of first word lines are in a plurality of columns and apart from each other in the first horizontal direction, and
the group of first word lines are connected to the one first horizontal extension and are connected to the one first word line contact through the second horizontal extension.

20. The semiconductor device of claim 18, wherein
the plurality of second word lines are in a plurality of columns and apart from each other in the first horizontal direction, and
the group of second word lines are connected to the another first horizontal extension and are connected to the one second word line contact through the another second horizontal extension.
